(19) United States
(12) Patent Application Publication
(10) Pub. No.: US 2021/0176878 A1
(43) Pub. Date: Jun. 10, 2021

(54) HOUSING COVER FOR A FIELD DEVICE

(71) Applicant: Endress+Hauser SE+Co. KG, Maulburg (DE)

(72) Inventors: Vitogiuseppe Di Cosola, Hartheim (DE); Jürgen Tanner, Kandern (DE); Alexander Stoppa, Schönsee (DE); Günther Irlbacher, Schönsee (DE)

(21) Appl. No.: 16/768,618

(22) PCT Filed: Oct. 24, 2018
(86) PCT No.: PCT/EP2018/079085

§ 371 Date: May 29, 2020

(30) Foreign Application Priority Data
Nov. 30, 2017 (DE) 10 2017 128 434.6

(51) Int. Cl. H05K 5/02; H05K 5/00; G01D 11/26; H05K 7/14

(52) U.S. Cl. CPC H05K 5/0239; H05K 7/1462; G01D 11/26; H05K 5/0017

(57) ABSTRACT

The present invention relates to a housing cover for a field device of automation technology, a housing having a corresponding housing cover as well as a field device having a corresponding housing. The housing cover includes a housing cover body having at least one opening, a viewing window, which can be placed in the opening, and a securement means for securing the housing cover, especially releasably, on a housing body of a housing of the field device. According to the invention, the viewing window is composed, at least partially, of an impact resistant material, especially a glass, preferably an alumino-silicate glass, a ceramic or a hybrid of a glass or a ceramic and a plastic.

The invention relates to a housing cover for a field device of automation technology, especially for a housing of such a field device, to a housing having a housing cover of the invention and to a field device having a housing of the invention.

Field devices of automation technology are, for example, fill level measuring devices, flowmeters, pressure- and temperature measuring devices, pH- and/or pH-redox potential measuring devices, and even conductivity measuring devices, which register corresponding process variables, fill level, flow, pressure, temperature, pH value, redox potential, and conductivity. The underlying measuring principles are sufficiently known from the state of the art, and are not individually set forth here. In the case of flowmeters, such are, especially Coriolis, ultrasonic, vortex, thermal and/or magnetically inductive flowmeters. Fill level measuring devices, in turn, are especially microwave, fill level measuring devices, ultrasonic, fill level measuring devices, time domain reflectometric, fill level measuring devices (TDR), radiometric, fill level measuring devices, capacitive, fill level measuring devices, conductive, fill level measuring devices and/or temperature sensitive, fill level measuring devices. In the case of pressure measuring devices, in contrast, such are, preferably, so-called absolute-, relative- or difference pressure devices, while temperature measuring devices frequently use thermocouples or temperature dependent resistances for ascertaining the temperature.

Fundamentally, a field device typically includes at least one sensor unit coming at least partially and at least at times in contact with the process and an electronics unit, which serves, for example, for signal registration, evaluation and/or feeding. In the context of the present invention, in principle, all measuring devices are referred to as field device, which are applied near to the process and which deliver, or process, process relevant information, thus, also remote I/Os, radio adapters, and, generally, electronic components, which are arranged at the field level. A large number of such field devices are produced and sold by the Endress+Hauser group of companies.

At least the electronics unit of such a field device is typically arranged in a housing. The most varied of embodiments are possible for a field device housing, depending on the type of field device, thus depending on the process variable to be determined and/or monitored, and/or depending on the application or use contemplated for the field device. Especially, different applications have different requirements for their housings. Thus, for housings for use in explosion endangered atmospheres, other conditions need to be taken into consideration than, for example, for applications in the chemicals industry, foods industry of the like. In the case of housings for use in explosion endangered atmospheres, of concern, especially, is safely to prevent the forming of sparks or at least to assure that sparks arising in the case of malfunction do not affect the environment. In such case, one basically distinguishes between different explosion protection types and explosion zones. The different requirements are described, in turn, for example, in the European ATEX- or the North American NEC- or CEC-Directives as well as the standards based thereon, EN, IEC, UL, CSA or NEC.

Components of a field device, which can trigger an ignition, are, for example, frequently installed in pressure-resistantly encapsulated housings, which can withstand a pressure arising in the case of an explosion. The propagation of the explosion is, thus, in principle, prevented by a suitable housing construction. For this, the explosion protection type “pressure-resistant encapsulation” (Ex-d) is used, which provides structural requirements for housings in such a manner that an escape of the explosion from the housing interior is not possible. Details relative to these requirements are given, for example, depending on region, in the standards EN60079-1, IEC 60079-1, UL2279 PT. 1, UL60079-1 and CSA E60079-1.

Typically, the components of a field device are arranged in a housing body forming a hollow space. The housing body is closable by means of a housing cover. For assuring a sufficient mechanical stability upon the occurrence of an explosion, such housings have comparatively thick walls and therewith are relatively expensive. Also, display elements for display of measured values or the like as well as interaction elements for adjusting settings in the field device on-site must in explosion endangered regions be arranged within the housing or in a separate housing part. Correspondingly, housing covers, as a rule, have a viewing window, which enables, for example, reading a display element. Interaction elements can, in turn, be provided, for example, by way of optical keys, which can be actuated through the viewing window. For assuring a high mechanical stability of a housing cover with viewing window, especially relative to an impact test or stability under pressure, high requirements as regards construction must be followed. For example, a viewing window is usually grouted in the housing cover. Furthermore, there are various requirements for materials and thickness of the viewing window.

Known from DE102004052497A1, for example, is a pressure resistantly encapsulated housing, in the case of which a display element is surrounded on all sides by a pressure resistant, transparent grout. In the case of damage in this case, however, the complete housing cover with integrated display element must be replaced.

An object of the present invention is, thus, to provide a housing cover with integrated viewing window, in the case of which an increased mechanical stability is achievable in simple manner.

The object is achieved by a housing cover as defined in claim 1, by a housing as defined in claim 14, and by a field device as defined in claim 15.

Regarding the housing cover, the object underpinning the invention is achieved by a housing cover for a field device of automation technology, comprising
a housing cover body having at least one opening
a viewing window, which can be placed in the opening, and
a securement means for securing the housing cover, especially releasably, on a housing body of a housing of the field device.

According to the invention, the viewing window is composed, at least partially, of an impact resistant material, especially a glass, preferably an alumino-silicate glass, a ceramic or a hybrid of a glass or a ceramic and a plastic.

Because of the increased impact resistance, an increased mechanical stability can be assured. Corresponding housing covers are, thus, well suited for use in explosion endangered regions. Especially, a corresponding housing cover can withstand an impact test of up to 4 J and a following pressure loading of >80 bar. In the case of conventional glasses, impact testing frequently leads to so-called microcracks, which can disadvantageously affect the stability of the glasses under pressure.

Compared with other glasses, alum ino-silicate glasses are distinguished, for example, by an especially high breaking- and scratch resistance. Especially, the alum ino-silicate glass can be a chemically prestressed alumino-silicate glass, in the case of which sodium ions are replaced in the surface of the glass by potassium ions in an ion exchange process conducted in a heated potassium salt melt (at about 400° C.). This leads to a glass, which is crack resistant under a point load of 40 N or more and which is at least two- to three times more scratch resistant than conventional glasses.

In an embodiment, the viewing window is grouted for connection with the housing cover body. The viewing window is then, in principle, framed in a predeterminable edge region into the housing cover body. A grouting of the viewing window into the housing cover is especially advantageous as regards the requirements of explosion protection class Ex-d.

It is, moreover, advantageous that the viewing window has a thickness of at least 10 mm.

In an especially preferred embodiment, the viewing window is composed of at least a first window pane and a second window pane. Preferably, the first and second window panes are arranged on top of one another. For example, the first and second window panes can be of different materials with different properties, especially mechanical properties. For a pressure resistant encapsulation corresponding to explosion protection class Ex-d, it is, for example, required that the viewing window can withstand a pressure loading after exposure to an impact loading. Mechanical impact loading can especially lead to microcracks at least in a region near to the surface of a window. These then act disadvantageously in the case of subsequent high pressure loading. Since two window panes are used, the different requirements to be fulfilled relative to a high resistance to crack- and scratch formation and relative to high stability in the face of pressure loading can be correspondingly arranged with targeting. For example, a first window pane facing the housing interior can have a high pressure resistance, while the second window pane facing the housing exterior can have an increased resistance to crack- and scratch formation.

Thus, advantageously, a first of the two window panes is composed at least partially of a temperature resistant glass, especially a borosilicate glass. Thus, borosilicate glass is distinguished by a high chemical durability, which is likewise a basic advantage, and it has a comparatively small coefficient of thermal expansion. In the case of the first window pane, it is, thus, preferably, a window pane for assuring high stability in the face of pressure loading.

Likewise or alternatively, a second of the two window panes is advantageously composed at least partially of an impact resistant material, especially a glass, preferably an alumino-silicate glass, a ceramic or a hybrid of a glass or a ceramic and a plastic. The second window pane serves, thus, in turn, for assuring a high resistance to scratching- and/or crack formation.

Preferably, the two window panes are arranged in such a manner that the second window pane faces outwards. In this way, the second window pane, which has a high resistance to scratching- and/or crack formation, faces the housing exterior, while the first, temperature resistant window pane, which serves for assuring a high resistance to pressure loading, faces the housing interior.

Another preferred embodiment provides that the two window panes have different thicknesses, especially the first window pane has a thickness of at least 10 mm and the second window pane a thickness of less than or equal to 5 mm. Preferably, thus, the thickness of the second window pane, which serves for preventing scratch- and/or crack formation, is less than the thickness of the first window pane.

Advantageously, the first and second window panes are at least sectionally connected together. In this way, an increased stability of the housing cover can be achieved.

Preferably, the connection is produced by means of a bonding method or by means of an adhesive, especially a transparent adhesive. The adhesive is preferably composed of at least one layer of a durably elastic composite material. For example, involved can be a so-called film connecting (an Optically Clear Adhesive, OCA) or a liquid connecting (a Liquid Optically Clear Adhesive, LOCA). Examples include silicone adhesives. The adhesive can be applied either sectionally, e.g. in a ring-shaped edge region between the two window panes, or completely over the interface between the two mutually facing surface regions of the two window panes. Advantageously, a viscosity of the adhesive is so selected that bubble formation between the two window panes can essentially be prevented.

Another especially preferred embodiment provides that the two window panes have differently large areas, especially different diameters.

In this regard, advantageously, the center points of the areas of the two window panes align with one another, wherein the area of the second window pane is less than the area of the first window pane and wherein an especially circularly shaped, edge region of the first window pane is not covered by the second window pane. With this ring-shaped edge region, the viewing window can, for example, be mounted into the housing cover body.

The two window panes can, on the one hand, be first connected together and then introduced into the housing cover body. On the other hand, it is likewise possible first to introduce the first window pane into the housing cover body, for example, to secure it by grouting, and then to connect the second window pane to the first window pane, for example, by bonding. In this way, for example, an existing housing cover of the invention can be retrofitted for increasing the mechanical stability, especially for use in an explosion endangered environment.

In an embodiment, the housing cover is embodied in such a manner that it is suitable for use in an explosion endangered environment.

The object underpinning the invention is achieved, furthermore, by a housing for a field device having a housing cover of the invention and by a field device of automation technology, comprising a sensor element, a field device electronics, and a housing of the invention.

It is to be noted here that the embodiments described in connection with the housing cover can be used mutatis mutandis also for the housing of the invention, and for the field device of the invention, and vice versa.

The invention will now be explained in greater detail based on the appended drawing, wherein equal elements are provided with equal reference characters. The figures of the drawing show as follows:

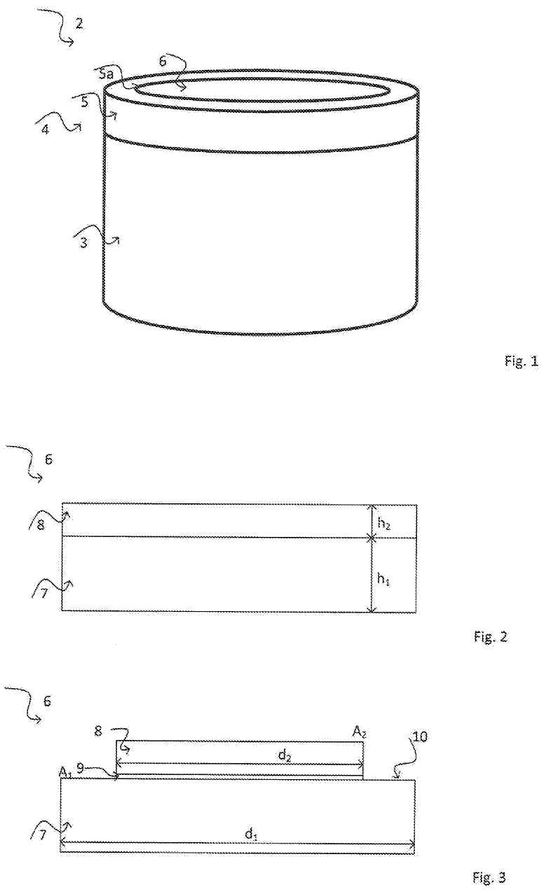

FIG. 1 a schematic view of a housing having a housing cover of the invention,

FIG. 2 a first embodiment of a housing cover of the invention having a viewing window composed of two window panes, and

FIG. 3 a second embodiment of a housing cover of the invention having a viewing window composed of two window panes.

FIG. 1 shows a housing 2 for a field device 1 (not shown) of automation technology. Housing 2 includes a housing body 3 having a hollow space, in which at least one component of the field device 1, for example, an electronics unit (not shown), is arranged. Housing body 3 is closed with a housing cover 4, which contains a viewing window integrated therein. Behind the viewing window can be located, for example, a display element or an interaction element, especially an optical, interaction element. The housing cover 4 is connected in known manner with the housing body. For example, screw- or flange connections are possible in this regard. Housing 2 is composed, for example, of a metal or a plastic.

Housing cover 4 includes a housing cover body 5 having an opening 5a, in which the viewing window 6 is secured. For example, the viewing window 6 is grouted in the housing cover body 5. The viewing window 6 is then, in principle, framed in an inner edge region of the housing cover-body 5. The viewing window is composed according to the invention at least partially of an impact resistant material, especially a glass, preferably an alumino-silicate glass, a ceramic or a hybrid of a glass or a ceramic and a plastic.

Viewing window 6 can, on the one hand, be a single element, such as shown in FIG. 1. Alternatively, the viewing window can, however, also be composed of at least two window panes 7,8, such as shown in FIGS. 2 and 3.

FIG. 2 shows a viewing window 6, which is composed of a first window pane 7 and a second window pane 8. In this embodiment, the second window pane 8 has a lesser thickness h₂ than the first window pane 7 with the thickness h₁. The second window pane 8 is composed, at least partially, of an impact resistant material, especially a glass, preferably an alumino-silicate glass, a ceramic or a hybrid of a glass or a ceramic and a plastic, and the first window pane is composed of a temperature resistant glass, especially a borosilicate glass. In such case, the first window pane 7 faces the housing interior, and the second window pane 8 is externally directed. The second window pane 8 assures a high resistance of the viewing window 6 to the formation of scratches and/or cracks, and, thus, a high mechanical stability against impacts. The first window pane 7 is distinguished, in turn, by a high stability under pressure, especially relative to an explosion occurring, in given cases, in the housing interior. The two window panes 7,8 are preferably connected together, for example, by means of a bonding method or by means of an adhesive, especially a transparent adhesive.

In the example of an embodiment shown in FIG. 2, the first window pane 7 and the second window pane 8 have essentially the same area. In contrast, in the example of an embodiment shown in FIG. 3, the second window pane 8 has a smaller diameter d₂ than the first window pane 7 with the diameter d₁. The center points of the two areas A₁ and A₂ align with one another, in such a manner that a ring-shaped edge region 10 of the first window pane 7 is not covered by the second window pane 8. Viewing window 6 can, for example, be mounted in the housing cover body 5 with this ring-shaped edge region.

Alternatively, it is also possible first to mount only the first window pane 7 in the housing cover body 5 and then apply the second window pane 8 on the first window pane 7. For this, the second window pane 8 can, for example, be adhered to the first window pane 7 by means of an adhesive 9. However, also other known securements can be used and fall within the scope of the present invention. In this way, for example, existing housing covers 4 can be retrofitted according to the invention.

### REFERENCE CHARACTERS

1 field device

2 housing

3 housing body

4 housing cover

5 housing cover body with opening 5a

6 viewing window

7 first window pane

8 second window pane

9 adhesive

10 ring-shaped edge region

h₁,h₂ thicknesses of the window panes 7, 8

d₁,d₂ diameters of the window panes 7, 8

A₁,A₂ areas of the window panes 7, 8

1-15. (canceled)

16. A housing cover for a field device of automation technology, comprising:
a housing cover body having at least one opening;
a viewing window, which can be placed in the opening; and
a securement means for releasably securing the housing cover on a housing body of a housing of the field device,
wherein the viewing window is composed at least partially of an impact-resistant material.

17. The housing cover as claimed in claim 16, wherein the impact-resistant material is a glass, an alumino silicate glass, a ceramic, or a hybrid of a glass or a ceramic and a plastic.

18. The housing cover as claimed in claim 16, wherein the viewing window is grouted in the housing cover body.

19. The housing cover as claimed in claim 16, wherein the viewing window has a thickness of at least 10 millimeters (mm).

20. The housing cover as claimed in claim 16, wherein the viewing window includes at least a first window pane and a second window pane.

21. The housing cover as claimed in claim 20, wherein the first window pane is composed at least partially of a temperature-resistant glass, including a borosilicate glass.

22. The housing cover as claimed in claim 21, wherein the second window pane is composed at least partially of an impact resistant material, including a glass, an alumino-silicate glass, a ceramic, or a hybrid of a glass or a ceramic and a plastic.

23. The housing cover as claimed in claim 22, wherein the two window panes are arranged such that the second window pane faces outwards.

24. The housing cover as claimed in claim 20, wherein the two window panes have different thicknesses, and wherein the first window pane has a thickness of at least 10 mm and the second window pane has a thickness of less than or equal to 5 mm.

25. The housing cover as claimed in claim 20, wherein the first window pane and the second window pane are at least sectionally connected together.

26. The housing cover as claimed in claim 25, wherein the connection is produced by a bonding method, or wherein the connection is produced by an adhesive, including a transparent adhesive.

27. The housing cover as claimed in claim 20, wherein the two window panes have differently large areas, including different diameters.

28. The housing cover as claimed in claim 27, wherein the center points of the areas of the two window panes align with one another, wherein the area of the second window pane is less than the area of the first window pane, and wherein a circularly shaped edge region of the first window pane is not covered by the second window pane.

29. The housing cover as claimed in claim 16, wherein the housing cover is embodied such that it is suitable for use in an explosion endangered environment.

30. A housing for a field device, comprising:
a housing cover including:
a housing cover body having at least one opening;
a viewing window, which can be placed in the opening; and
a securement means for releasably securing the housing cover on a housing body of the housing for the field device,
wherein the viewing window is composed at least partially of an impact-resistant material.

31. A field device of automation technology, comprising:
a sensor element;
a field device electronics; and
a housing, including a housing cover including:
a housing cover body having at least one opening;
a viewing window, which can be placed in the opening; and
a securement means for releasably securing the housing cover on a housing body of the housing of the field device,
wherein the viewing window is composed at least partially of an impact-resistant material.
